(19) United States
(12) Patent Application Publication
(10) Pub. No.: US 2021/0217894 A1
(43) Pub. Date: Jul. 15, 2021

(54) CMOS THIN FILM TRANSISTOR, MANUFACTURING METHOD THEREOF AND ARRAY SUBSTRATE

(71) Applicants: Ordos Yuansheng Optoelectronics Co., Ltd., Ordos, Inner Mongolia (CN); BOE Technology Group Co., Ltd., Beijing (CN)

(72) Inventors: Lei YAO, Beijing (CN); Yezhou FANG, Beijing (CN); Feng LI, Beijing (CN); Lei YAN, Beijing (CN); Jinjin XUE, Beijing (CN); Chenglong WANG, Beijing (CN); Yanyan MENG, Beijing (CN); Jinfeng WANG, Beijing (CN); Lin HOU, Beijing (CN); Zhixuan GUO, Beijing (CN); Yuanbo LI, Beijing (CN); Xiaofang LI, Beijing (CN)

(21) Appl. No.: 16/963,937

(22) PCT Filed: Dec. 25, 2019
(86) PCT No.: PCT/CN2019/128284

§ 371 Date: Jul. 22, 2020

(30) Foreign Application Priority Data
Feb. 27, 2019 (CN) 201910146805.X

(51) Int. Cl. H01L 29/786; H01L 27/092; H01L 29/66

(52) U.S. Cl. CPC H01L 29/78621; H01L 29/6675; H01L 29/78672; H01L 27/0922

(57) ABSTRACT

A CMOS thin film transistor, a method for manufacturing the same, and an array substrate are provided. The method includes: forming a semiconductor layer including an N-type region and a P-type region on a substrate, the N-type region is divided into a first region, a second region, a third region, a fourth region and a fifth region, the P-type region is divided into a sixth region, a seventh region and an eighth region; performing first N-type ion doping on the first region and the fifth region; performing first P-type ion doping on the N-type region; performing second P-type ion doping on the N-type region and the P-type region; performing second N-type ion doping on the first region, the second region, the fourth region, the fifth region, the sixth region and the eighth region; and performing third P-type ion doping on the sixth region and the eighth region.

### CROSS-REFERENCE TO RELATED APPLICATIONS

This is a National Phase Application filed under 35 U.S.C. 371 as a national stage of PCT/CN2019/128284, filed Dec. 25, 2019, an application claiming the benefit of Chinese Application No. 201910146805.X, filed Feb. 27, 2019, the content of each of which is hereby incorporated by reference in its entirety.

### TECHNICAL FIELD

The present disclosure relates to the field of display technology, and in particular, to a CMOS thin film transistor, a method for manufacturing the CMOS thin film transistor, and an array substrate.

### BACKGROUND

In an existing CMOS (complementary metal oxide semiconductor) product of a TFT-LCD, a MOS transistor (field effect transistor) needs to be formed by multiple times of channel doping (P-type ion doping or N-type ion doping) in a manufacturing process of an array substrate, but due to differences in design and working principle of a PMOS (P-type metal oxide semiconductor) and an NMOS (N-type metal oxide semiconductor), multiple times of doping processes need to be performed successively in the manufacturing process of the array substrate, including: channel doping, threshold voltage doping (Vth doping), N+ doping, lightly doped drain (LDD) doping and P+ doping, which results in a complex process flow, a long process time and a high cost.

### SUMMARY

In an aspect of the present disclosure, there is provided a method for manufacturing a CMOS thin film transistor. According to an embodiment of the present disclosure, the method includes:

step 1, forming a semiconductor layer on a substrate, the semiconductor layer including an N-type region and a P-type region which are arranged in a single layer and are spaced apart from each other,

wherein the N-type region is divided into a first region, a second region, a third region, a fourth region and a fifth region and used for forming an N-type thin film transistor, the first region is used for forming a first heavily doped drain region, the second region and the fourth region are used for forming lightly doped drain regions, the third region is used for forming a first gate inner region, and the fifth region is used for forming a first heavily doped source region,

the P-type region is divided into a sixth region, a seventh region and an eighth region and used for forming a P-type thin film transistor, the sixth region is used for forming a second heavily doped drain region, the seventh region is used for forming a second gate inner region, and the eighth region is used for forming a second heavily doped source region;

step 2, performing a first N-type ion doping on the first region and the fifth region;

step 3, performing a first P-type ion doping on the N-type region;

step 4, performing a second P-type ion doping on the N-type region and the P-type region after the step 3;

step 5, performing a second N-type ion doping on the first region, the second region, the fourth region, the fifth region, the sixth region and the eighth region after the step 4; and

step 6, performing a third P-type ion doping on the sixth region and the eighth region after the step 5, wherein the first N-type ion doping and the first P-type ion doping are performed by using a single halftone mask plate.

According to an embodiment of the present disclosure, steps of the first N-type ion doping and the first P-type ion doping include: forming a first patterned photoresist layer on an upper surface of the semiconductor layer by using the halftone mask plate, wherein the first patterned photoresist layer includes a first layer and a second layer, the first layer covers a surface of the P-type region, and the second layer covers surfaces of the second region, the third region and the fourth region, a thickness of the second layer is smaller than a thickness of the first layer; performing the first N-type ion doping on the first region and the fifth region which are exposed; removing the second layer, and thinning the first layer so as to obtain a second patterned photoresist layer, wherein the second patterned photoresist layer covers the surface of the P-type region; performing the first P-type ion doping on the N-type region which is exposed; and removing the second patterned photoresist layer.

According to an embodiment of the present disclosure, by an ashing process, the second layer is removed and the first layer is thinned, so as to obtain the second patterned photoresist layer.

According to an embodiment of the present disclosure, the thickness of the second layer ranges from 30% of the thickness of the first layer to 70% of the thickness of the first layer.

According to an embodiment of the disclosure, the thickness of the first layer ranges from 1 μm to 2.5 μm, the thickness of the second layer ranges from 0.5 μm to 1.75 μm, and a time duration of the ashing process ranges from 10 seconds to 40 seconds.

According to an embodiment of the present disclosure, a thickness of the second patterned photoresist layer ranges from 30% of the thickness of the first layer to 70% of the thickness of the first layer.

According to an embodiment of the present disclosure, the method further includes: after the second P-type ion doping and before the second N-type ion doping, forming a gate insulating layer on surfaces of the N-type region and the P-type region; and forming a first gate electrode and a second gate electrode on a surface of the gate insulating layer, wherein an orthographic projection of the first gate electrode on the substrate is overlapped with an orthographic projection of the third region on the substrate, an orthographic projection of the second gate electrode on the substrate is overlapped with an orthographic projection of the seventh region on the substrate, and the second N-type ion doping is performed by taking the first gate electrode and the second gate electrode as masks.

According to an embodiment of the present disclosure, the step of performing the third P-type ion doping includes: forming a third patterned photoresist layer on the surface of the gate insulating layer corresponding to the N-type region, wherein the third patterned photoresist layer covers the first gate electrode, and the third patterned photoresist layer and the second gate electrode are used as masks for performing the third P-type ion doping on the sixth region and the eighth region.

According to an embodiment of the present disclosure, the semiconductor layer is a polycrystalline layer.

In another aspect of the present disclosure, there is provided a CMOS thin film transistor. According to an embodiment of the present disclosure, the CMOS thin film transistor is manufactured by the method described above. Therefore, the CMOS thin film transistor has advantages of being manufactured by a short period, a low cost and having good characteristics and service performances. As can be appreciated by those skilled in the art, the CMOS thin film transistor has all features and advantages of the method described above, which will not be described in detail here.

According to an embodiment of the present disclosure, the CMOS thin film transistor includes an N-type thin film transistor and a P-type thin film transistor, wherein the N-type thin film transistor includes a first heavily doped drain region, lightly doped drain regions, a first gate inner region, and a first heavily doped source region, an orthographic projection of the first gate inner region on a substrate is overlapped with an orthographic projection of a first gate electrode on the substrate, the lightly doped drain regions are disposed at two opposite ends of the first gate inner region, the first heavily doped drain region is disposed at an end of the lightly doped drain region away from the first gate inner region, and the first heavily doped source region is disposed at another end of the lightly doped drain region away from the first gate inner region; the P-type thin film transistor includes a second heavily doped drain region, a second gate inner region and a second heavily doped source region, an orthographic projection of the second gate inner region on the substrate is overlapped with an orthographic projection of the second gate electrode on the substrate, and the second heavily doped drain region and the second heavily doped source region are respectively arranged at two opposite ends of the second gate inner region.

In yet another aspect of the present disclosure, there is provided an array substrate. According to an embodiment of the present disclosure, the array substrate includes the CMOS thin film transistor described above. Therefore, in addition to ensuring good characteristics and service performances of the array substrate, the array substrate is manufactured by a short period, and a cost for manufacturing the array substrate is reduced, resulting in improved market competitiveness. As will be understood by those skilled in the art, the array substrate has all features and advantages of the CMOS thin film transistor described above, which will not be described in detail here.

### DESCRIPTION OF DRAWINGS

FIG. 1 is a flow chart of a method for manufacturing a CMOS thin film transistor in an embodiment of the present disclosure.

FIG. 2 is a structure obtained during manufacturing a CMOS thin film transistor in an embodiment of the present disclosure.

FIG. 3 is a structure obtained during manufacturing a CMOS thin film transistor in an embodiment of the present disclosure.

FIG. 4 is a structure obtained during manufacturing a CMOS thin film transistor in an embodiment of the present disclosure.

FIG. 5 is a flow chart of a method for manufacturing a CMOS thin film transistor in an embodiment of the present disclosure.

FIG. 6 is a structure obtained during manufacturing a CMOS thin film transistor in an embodiment of the present disclosure.

FIG. 7 is a structure obtained during manufacturing a CMOS thin film transistor in an embodiment of the present disclosure.

FIG. 8 is a structure obtained during manufacturing a CMOS thin film transistor in an embodiment of the present disclosure.

FIG. 9 is a structure obtained during manufacturing a CMOS thin film transistor in an embodiment of the present disclosure.

FIG. 10 is a structure obtained during manufacturing a CMOS thin film transistor in an embodiment of the present disclosure.

FIG. 11 is a structure obtained during manufacturing a CMOS thin film transistor in an embodiment of the present disclosure.

FIG. 12 is a structure obtained during manufacturing a CMOS thin film transistor in an embodiment of the present disclosure.

FIG. 13 is a structure obtained during manufacturing a CMOS thin film transistor in an embodiment of the present disclosure.

FIG. 14 is a structure obtained during manufacturing a CMOS thin film transistor in an embodiment of the present disclosure.

FIG. 15 is a schematic diagram showing a structure of a CMOS thin film transistor in an embodiment of the present disclosure.

### DESCRIPTION OF EMBODIMENTS

Embodiments of the present disclosure are described in detail below. The embodiments described below are illustrative and are intended to explain the present disclosure only and cannot be understood as a limitation to the present disclosure. For embodiments without specifying particular techniques or conditions, they can be performed according to techniques or conditions described in the related art or according to a product specification.

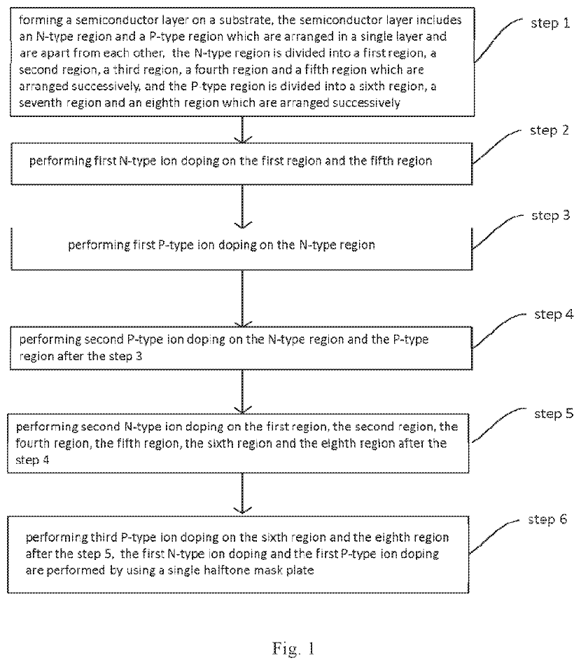

In an aspect of the present disclosure, there is provided a method for manufacturing a CMOS thin film transistor, which solves at least one of technical problems in the related art to some extent. An object of the present disclosure is to provide the method for manufacturing the CMOS thin film transistor, which can simplify process flow, shorten period of manufacturing process, or reduce cost of manufacturing. According to an embodiment of the present disclosure, referring to FIG. 1, the method includes following steps 1 to 6.

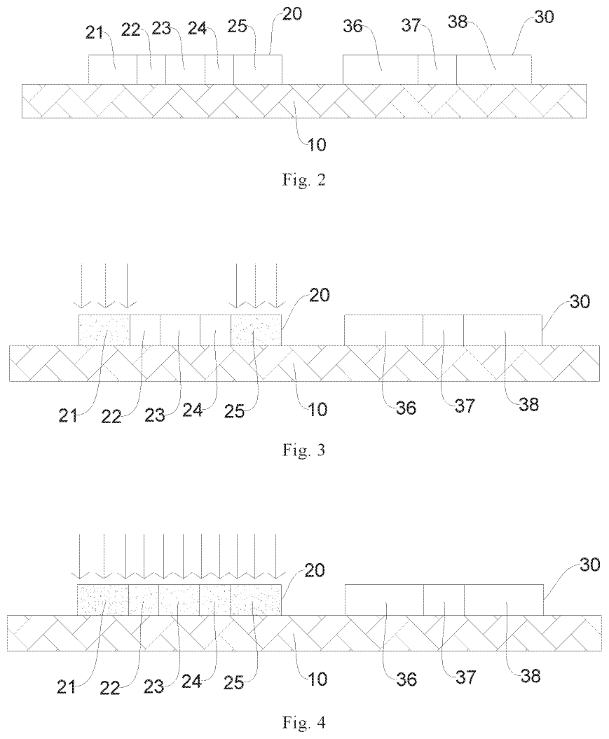

At step 1, forming a semiconductor layer on a substrate 10, where the semiconductor layer includes an N-type region 20 and a P-type region 30 which are arranged in a single layer and are spaced apart from each other, referring to FIG. 2, the N-type region 20 is divided into a first region 21, a second region 22, a third region 23, a fourth region 24 and a fifth region 25 which are arranged successively, the N-type region 20 is used for forming an N-type thin film transistor, the first region is used for forming a first heavily doped drain region, the second region and the fourth region are used for forming lightly doped drain regions, the third region is used for forming a first gate inner region, and the fifth region is used for forming a first heavily doped source region; the P-type region 30 is divided into a sixth region 36, a seventh region 37 and an eighth region 38 which are arranged successively, the P-type region 30 is used for forming a P-type thin film transistor, the sixth region is used for forming a second heavily doped drain region, the seventh region is used for forming a second gate inner region, and the eighth region is used for forming a second heavily doped source region.

In order to facilitate understanding of the technical solution, the above doped regions are briefly described as follows:

the first heavily doped drain region and the first heavily doped source region are respectively used for being electrically coupled to a drain electrode and a source electrode of the N-type thin film transistor, are doped by high-concentration N-type ions (such as phosphorus ions) to provide a large amount of free electrons for the N-type thin film transistor to be turned on, and each of such regions has a small resistance and can be equivalent to a conductor;

in the lightly doped drain region, a hot carrier effect is improved by a low-concentration doping, a principle thereof is that a relative low dosage of ions (compared with the heavily doped source and drain regions) are injected into the second region and the fourth region, and the dosage of the injected ions is between a doping amount of each of the heavily doped source and drain regions and a doping amount of the gate inner region, so that a certain concentration buffer region is formed, thereby an edge electric field gradient and the hot carrier effect at the drain electrode are reduced, and a leakage current of the N-type thin film transistor is reduced;

the first gate inner region and the second gate inner region are used for controlling the semiconductor layer to be in a conducting state or not, when a positive voltage is applied to the N-type thin film transistor, a portion of the free electrons in the lightly doped drain region are transferred to a surface of the semiconductor (the semiconductor may be polycrystalline silicon) in the first gate inner region, so that the semiconductor layer of the N-type thin film transistor is in the conducting state, when a negative voltage or no voltage is applied to the N-type thin film transistor, the electrons in the lightly doped drain region cannot be transferred to the first gate inner region, the resistance in the first gate inner region is very large, and the semiconductor layer of the N-type thin film transistor is in a non-conducting state; when a negative voltage is applied to the P-type thin film transistor, a portion of holes in the lightly doped drain region are transferred to the second gate inner region, so that the semiconductor layer of the P-type thin film transistor is in the conducting state, and when a positive voltage or no voltage is applied to the P-type thin film transistor, the holes in the lightly doped drain region cannot be transferred to the second gate inner region, the resistance in the second gate inner region is very large, so that the semiconductor layer of the P-type thin film transistor is in the non-conducting state;

the second heavily doped drain region and the second heavily doped source region are respectively used for being electrically coupled to a drain electrode and a source electrode of the P-type thin film transistor, are doped by high-concentration P-type ions (such as boron ions) to provide a large amount of holes for the P-type thin film transistor to be turned on, and each of such regions has a small resistance and can be equivalent to a conductor. According to an embodiment of the present disclosure, a material for forming the substrate is not limited, and those skilled in the art can flexibly select the material according to actual requirements. In some embodiments of the present disclosure, the material for forming the substrate includes, but is not limited to, polymer or glass.

According to an embodiment of the present disclosure, for ensuring good characteristics of the CMOS thin film transistor, the semiconductor layer is a polycrystalline layer, so that the semiconductor layer has relative large amount of carriers and better electrical characteristics. According to an embodiment of the present disclosure, the method for forming the semiconductor layer is not limited, and those skilled in the art can flexibly select the method according to actual situations. In some embodiments of the present disclosure, the method for forming the semiconductor layer (taking the polycrystalline layer as an example) includes: forming an amorphous silicon (a-Si) layer on the substrate by a chemical vapor deposition method, such as a plasma enhanced chemical vapor deposition method, and then performing an excimer laser annealing (ELA) on the amorphous silicon layer to obtain the polycrystalline silicon layer.

At step 2, performing a first N-type ion doping (N+ Doping) on the first region 21 and the fifth region 25, and the schematic diagram of the structure is shown in FIG. 3. Therefore, through the first N-type ion doping, a better ohmic contact and a low series resistance can be provided for the N-type MOS transistor (corresponding to the N-type region).

According to an embodiment of the present disclosure, a doping concentration and energy of the first N-type ion doping are not limited, and those skilled in the art can flexibly select the doping concentration and the energy according to actual situations. In some embodiments of the present disclosure, the first N-type ion doping has a doping concentration ranging from 1E14 to 8E14 and energy ranging from 10 kEV to 60 kEV.

At step 3, performing a first P-type ion doping (Vth Doping) on the N-type region 20 (including the first region to the fifth region) after the step 2, and the schematic diagram of the structure is shown in FIG. 4. In such way, through the first P-type ion doping, a better ohmic contact and a low series resistance are provided for the N-type thin film transistor (N-type MOS transistor, corresponding to the P-type region).

According to the embodiment of the present disclosure, a doping concentration and energy of the first P-type ion doping are not limited, and those skilled in the art can flexibly select the doping concentration and the energy according to actual situations. In some embodiments of the present disclosure, the first P-type ion doping has a doping concentration ranging from 1E14 to 8E14 and energy ranging from 10 kEV to 60 kEV.

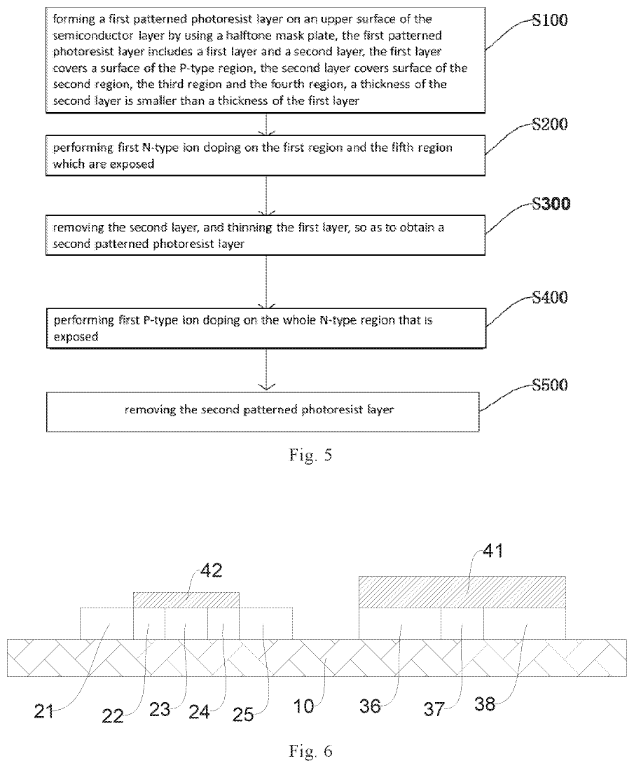

According to an embodiment of the present disclosure, the first N-type ion doping and the first P-type ion doping are performed by using a single halftone mask plate, and referring to FIG. 5, include following steps S100 to S500.

At step S100, forming a first patterned photoresist layer on an upper surface of the semiconductor layer by using a halftone mask plate, the first patterned photoresist layer includes a first layer 41 and a second layer 42, the first layer 41 covers a surface of the P-type region 30, the second layer 42 covers surfaces of the second region 22, the third region 23 and the fourth region 24, where a thickness of the second layer 42 is smaller than a thickness of the first layer 41, and the schematic diagram of the structure is shown in FIG. 6.

According to an embodiment of the disclosure, the thickness of the second layer ranges from 30% of the thickness of the first layer to 70% of the thickness of the first layer, such as 30%, 35%, 40%, 50%, 55%, 60%, 65% or 70% of the thickness of the first layer. Therefore, the second layer can effectively prevent doped ions from entering the second region 22, the third region 23 and the fourth region 24, and the second layer can be effectively removed in a subsequent process, and the first layer can be prevented from being thinned to be too thin, so that the ions cannot enter the P-type region during the first P-type ion doping, and characteristics of the CMOS thin film transistor are not influenced.

In an embodiment of the present disclosure, specific thicknesses of the first layer and the second layer are not particularly required, and those skilled in the art can flexibly design the thicknesses according to practical situations such as dosage and energy of ion doping, and in some examples, the thickness of the first layer is 1.5 μm, and the thickness of the second layer is 0.75 μm.

According to the embodiment of the present disclosure, the method for forming the first patterned photoresist layer by using the halftone mask plate 50 is not limited, and those skilled in the art can flexibly select a conventional technical means according to actual requirements to implement the method, specifically:

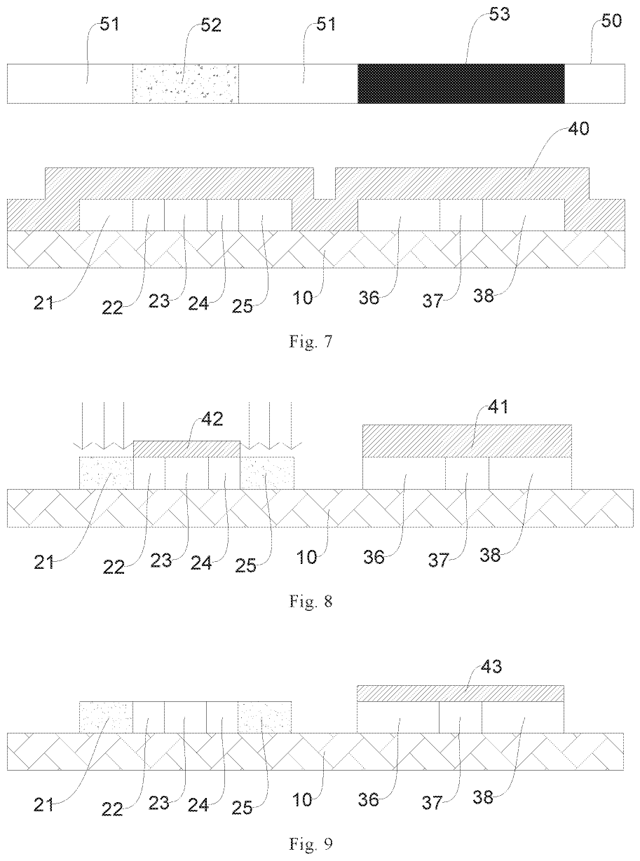

in some embodiments of the present disclosure, a positive photoresist layer 40 is first formed on the semiconductor layer, and the positive photoresist layer 40 is exposed by using the halftone mask plate 50, where a full exposure region 51 of the halftone mask plate 50 is disposed corresponding to the positive photoresist layer 40 covered on surfaces of the first region 21 and the fifth region 25, a half exposure region 52 of the halftone mask plate 50 is disposed corresponding to the positive photoresist layer 40 covered on surfaces of the second region 22, the third region 23, and the fourth region 24, and a non-exposure region 53 of the halftone mask plate 50 is disposed corresponding to the positive photoresist layer 40 covered on the surface of the P-type region 30, and the schematic diagram of the structure is shown in FIG. 7, and then after exposure and development, the first patterned photoresist layer including the first layer 41 and the second layer 42 with different thicknesses as shown in FIG. 6 is obtained.

In other embodiments of the present disclosure, a negative photoresist layer is first formed on the semiconductor layer, and the negative photoresist layer is exposed by using a halftone mask plate, where a non-exposure region of the halftone mask plate is disposed corresponding to the negative photoresist layer covered on the surfaces of the first region 21 and the fifth region 25, a half exposure region 52 of the halftone mask plate is disposed corresponding to the negative photoresist layer covered on the surfaces of the second region 22, the third region 23, and the fourth region 24, and a full exposure region of the halftone mask plate is disposed corresponding to the negative photoresist layer (not shown in the figure) covered on the surface of the P-type region 30, and then after exposure and development, the first patterned photoresist layer including the first layer 41 and the second layer 42 with different thicknesses as shown in FIG. 6 is obtained.

At step S200: performing first N-type ion doping on the first region 21 and the fifth region 25 which are exposed, and the schematic diagram of the structure is shown in FIG. 8.

According to an embodiment of the present disclosure, requirements for the first N-type ion doping performed here are consistent with those for the first N-type ion doping in the step 2, and thus will not be described in detail here.

At step S300: removing the second layer 42, and thinning the first layer 41, so as to obtain a second patterned photoresist layer 43, where the second patterned photoresist layer 43 covers the surface of the P-type region 30, and the schematic diagram of the structure is shown in FIG. 9.

According to an embodiment of the present disclosure, a thickness of the second patterned photoresist layer ranges from 30% of the thickness of the first layer to 70% of the thickness of the first layer, such as 30%, 35%, 40%, 50%, 55%, 60%, 65% or 70% of the thickness of the first layer. Therefore, the second patterned photoresist layer obtained by thinning the first layer would not be too thin, and therefore the ions are effectively prevented from entering the P-type region during the first P-type ion doping, and the characteristics of the CMOS thin film transistor are not influenced.

According to an embodiment of the present disclosure, in order to better removing of the second layer and thinning of the first layer, by an ashing process, the second layer 42 is removed and the first layer 41 is thinned so as to obtain the second patterned photoresist layer 43, specifically, the second patterned photoresist layer is subjected to an ashing treatment by using 02 gas during the ashing process, and a time duration of the ashing process is precisely controlled so as to effectively remove a first layer of photoresist (PR), and a second layer of photoresist with a certain thickness is remained, so that the second patterned photoresist layer 43 with the certain thickness is obtained, and it is ensured that the second patterned photoresist layer can block ions from being doped into the P-type region during the first P-type ion doping.

According to an embodiment of the present disclosure, those skilled in the art can vary specific thicknesses of the first layer and the second layer, and in some embodiments of the present disclosure, the first layer has a thickness ranging from 1 μm to 2.5 μm (such as 1 μm, 1.2 μm, 1.4 μm, 1.6 μm, 1.8 μm, 2.0 μm, 2.2 μm, 2.3 μm, 2.5 μm), the second layer has a thickness ranging from 0.5 μm to 1.75 μm (such as 0.5 μm, 0.7 μm, 0.9 μm, 1.0 μm, 1.1 μm, 1.3 μm, 1.5 μm, 1.6 μm, 1.75 μm), and the time duration of the ashing process ranges from 10 seconds to 40 seconds, such as 10 seconds, 15 seconds, 20 seconds, 25 seconds, 30 seconds, 35 seconds, or 40 seconds. Therefore, the time duration of the ashing process can be flexibly set by those skilled in the art according to practical conditions such as the specific thicknesses of the first layer and the second layer, so as to ensure that the second patterned photoresist layer with a proper thickness is obtained while the second layer is effectively removed.

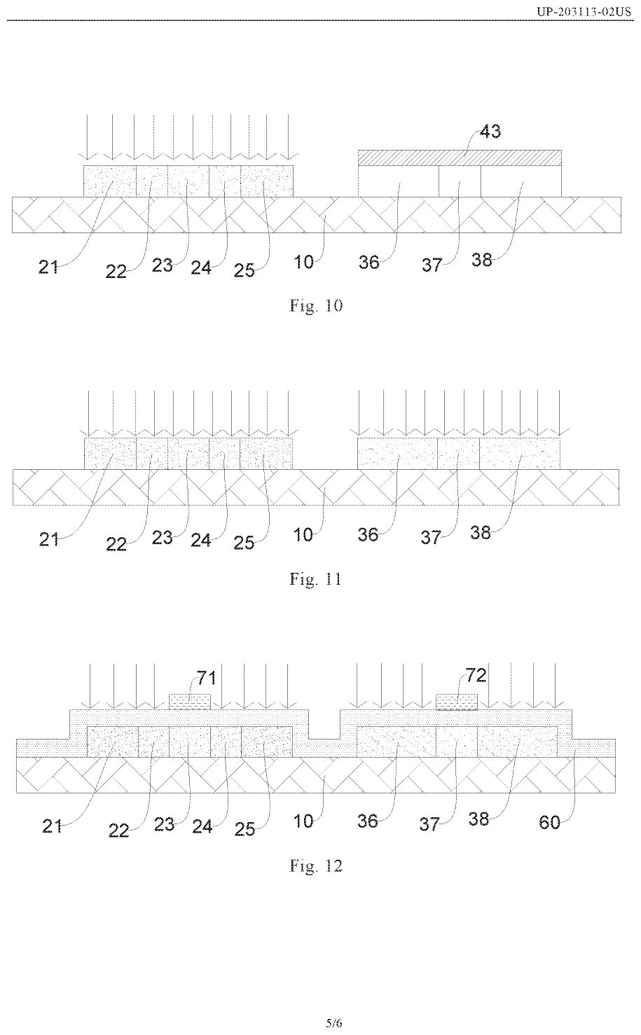

At step S400: performing a first P-type ion doping on the whole N-type region 20 that is exposed, and the schematic diagram of the structure is shown in FIG. 10.

According to an embodiment of the present disclosure, requirements for the first P-type ion doping performed here are consist with those for the first P-type ion doping in the step 3, and thus will not be described in detail here.

At step S500: removing the second patterned photoresist layer 43, and the schematic diagram of the structure is shown in FIG. 4.

According to an embodiment of the present disclosure, the method for removing the second patterned photoresist layer has no special requirement, and those skilled in the art can flexibly select the method according to actual situations. In an embodiment of the present disclosure, the second patterned photoresist layer may be removed by an ashing process, or a corresponding developing solution may be used according to a specific photoresist type of the second patterned photoresist layer, so as to effectively and completely remove the second patterned photoresist layer without affecting performances of the semiconductor layer.

At the step 4, performing a second P-type ion doping (Channel Doping) on the N-type region 20 and the P-type region 30 after the step 3, and the schematic diagram of the structure is shown in FIG. 11. Therefore, by the first P-type ion doping and the second P-type ion doping, a difference of injection amount of doping ions in the semiconductor layer is generated, and a threshold voltage of the CMOS thin film transistor is adjusted.

According to an embodiment of the present disclosure, a doping concentration and energy of the second P-type ion doping are not limited, and those skilled in the art can flexibly select the doping concentration and the energy according to practical situations. In some embodiments of the present disclosure, the doping concentration of the second P-type ion doping ranges from 1E14 to 8E14, and the energy ranges from 10 kEV to 60 kEV.

At step 5, performing a second N-type ion doping (LDD Doping) on the first region 21, the second region 22, the fourth region 24, the fifth region 25, the sixth region 36 and the eighth region 38 after the step 4, and the schematic diagram of the structure is shown in FIG. 12. Therefore, by the second N-type ion doping, a better ohmic contact and a low series resistance are provided for the CMOS thin film transistor.

According to an embodiment of the present disclosure, a doping concentration and energy of the second N-type ion doping are not limited, and those skilled in the art can flexibly select the doping concentration and the energy according to practical situations. In some embodiments of the present disclosure, the doping concentration of the second N-type ion doping ranges from 1E14 to 8E14, and the energy ranges from 10 kEV 60 kEV.

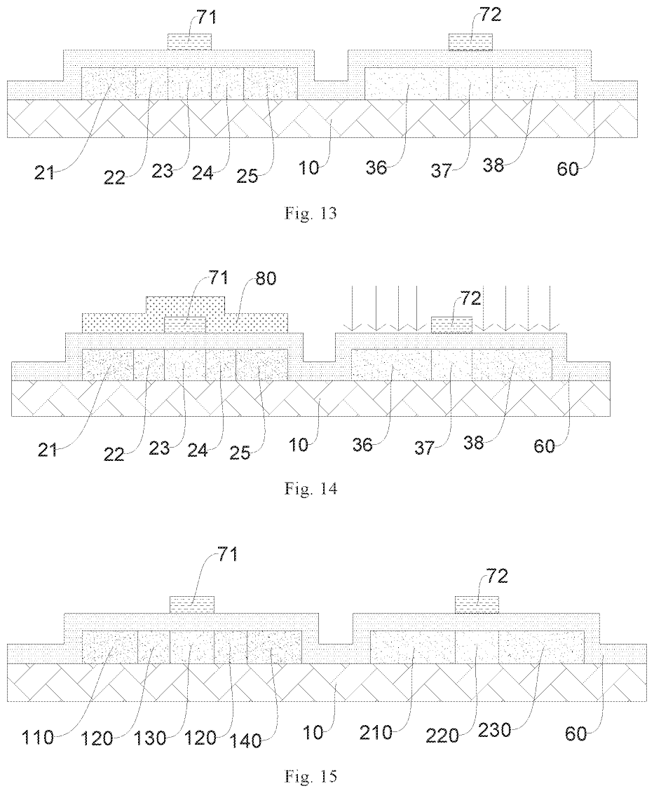

According to an embodiment of the present disclosure, in order to simplify the process flow and reduce the cost on the premise of ensuring good characteristics of the CMOS thin film transistor, referring to FIGS. 12 and 13, the method further includes: after the second P-type ion doping and before the second N-type ion doping, forming a gate insulating layer 60 on the surfaces of the N-type region 20 and the P-type region 30; and forming a first gate electrode 71 and a second gate electrode 72 on a surface of the gate insulating layer 60, where an orthographic projection of the first gate electrode 71 on the substrate 10 is overlapped with an orthographic projection of the third region 23 on the substrate 10, an orthographic projection of the second gate electrode 72 on the substrate 10 is overlapped with an orthographic projection of the seventh region 37 on the substrate 10, and the second N-type ion doping is performed by taking the first gate electrode and the second gate electrode as masks. Therefore, the first gate electrode and the second gate electrode are used as masks for ion doping, so that one mask can be saved, and the period of the process can be shortened.

According to an embodiment of the present disclosure, the method and the material for forming the gate insulating layer are not limited, and any method available in the related art may be adopted by those skilled in the art. In some embodiments of the present disclosure, the method for forming the gate insulating layer includes, but is not limited to, a chemical vapor deposition (such as plasma enhanced chemical vapor deposition) method or a physical vapor deposition (such as magnetron sputtering) method; the material for forming the gate insulating layer includes, but is not limited to, silicon oxide, silicon nitride, silicon oxynitride, an organic insulating material, and the like. In such way, the gate insulating layer has good service performances, the process is mature, and it is easy to realize industrial production.

According to an embodiment of the present disclosure, the method and the material for forming the first gate electrode and the second gate electrode are not limited, and those skilled in the art can flexibly select the material according to actual situations. In some embodiments of the present disclosure, the step of forming the first gate electrode and the second gate electrode includes: depositing a gate metal layer on a surface of the gate insulating layer first, and then obtaining the first gate electrode and the second gate electrode through an etching process; the material for forming the first gate electrode and the second gate electrode includes, but is not limited to, nickel, tungsten, molybdenum, chromium, nickel manganese alloy, nickel chromium alloy, nickel molybdenum iron alloy, tungsten molybdenum alloy, and the like. In such way, the first gate electrode and the second gate electrode made of the material mentioned above have good characteristics.

At step 6, performing a third P-type ion doping (P+ Doping) on the sixth region 36 and the eighth region 38 after the step 5, to obtain an N-type thin film transistor (N-type MOS transistor, corresponding to the N-type region) and a P-type thin film transistor (P-type MOS transistor, corresponding to the P-type region), so as to obtain a CMOS thin film transistor, and the schematic diagram of the structure is shown in FIG. 14. Therefore, by the third P-type ion doping, a better ohmic contact and a low series resistance can be provided for the P-type MOS transistor.

According to an embodiment of the present disclosure, a doping concentration and energy of the third P-type ion doping are not limited, and those skilled in the art can flexibly select the doping concentration and the energy according to actual situations. In some embodiments of the present disclosure, the doping concentration of the third P-type ion doping ranges from 1E14 to 8E14, and the energy ranges from 10 kEV to 60 kEV.

According to an embodiment of the present disclosure, the step of performing the third P-type ion doping includes: forming a photoresist layer on a surface of the gate insulating layer 60 away from the substrate, and then obtaining a third patterned photoresist layer 80 shown in FIG. 14 through exposure and development, that is, the third patterned photoresist layer 80 is formed on the surface of the N-type region 20 corresponding to the gate insulating layer 60, the third patterned photoresist layer 80 covers the first gate electrode 71, and the third P-type ion doping is performed on the sixth region 36 and the eighth region 38 by using the third patterned photoresist layer 80 and the second gate electrode 72 as masks. Certainly, it should be understood by those skilled in the art that the third patterned photoresist layer 80 is removed in a subsequent step, where the specific method for removing the third patterned photoresist layer 80 is not particularly limited, and the third patterned photoresist layer 80 may be removed by an ashing process, or by using developing solution, and those skilled in the art can flexibly select the method according to actual requirements.

According to an embodiment of the present disclosure, in the manufacturing process described above, by adjusting a sequence of steps of doping in the related art and realizing the first N-type ion doping and the first P-type ion doping through the single halftone mask plate, one mask process can be reduced, so that the period of manufacturing process is shortened, the manufacturing cost is reduced, and the good characteristics and the service performances of the CMOS thin film transistor can be still ensured; in addition, in the technical solution of the present disclosure, the first N-type ion doping (N+ Doping) is performed before the gate insulating layer (GI layer) is formed, and compared with the technical solution in which the first N-type ion doping (N+ Doping) is performed after the gate insulating layer is formed, the technical solution of the present disclosure is characterized in that, without blocking of the gate insulating layer (if the first N-type ion doping (N+Doping) is performed after the gate insulating layer is formed, when the doping ions are injected in an accelerated manner, most of the ions remain in the GI layer due to being blocked, the injection effect is relatively poor), the dosage of the ions and the energy to be injected are relative low. In such way, a waste of material can be avoided, the cost is reduced, and an aging of equipment is delayed.

According to an embodiment of the present disclosure, compared with that any two other steps in the five steps of ion doping are combined to use the halftone mask plate, the first N-type ion doping and the first P-type ion doping in the present disclosure adopting the single halftone mask plate is easier to be implemented, and the process compatibility is better (for example, the second N-type ion doping adopts the first gate electrode and the second gate electrode as masks, the third P-type ion doping and any other step of ion doping are inconvenient to use the halftone mask plate, the second P-type ion doping is to dope ions in both the N-type region and the P-type region, and no mask plate is needed), so that not only the manufacturing flow of the CMOS thin film transistor can be shortened, but also the manufacturing cost of the CMOS thin film transistor can be reduced, and further the manufacturing efficiency of the CMOS thin film transistor can be improved.

According to an embodiment of the present disclosure, the specific type of ions in the N-type ion doping (including the first N-type ion doping and the second N-type ion doping) is not limited, and those skilled in the art can flexibly select the ions according to actual requirements, for example, the ions may be phosphorus ions or arsenic ions; the specific type of ions in the P-type ion doping (including the first P-type ion doping, the second P-type ion doping, and the third P-type ion doping) is not limited, and those skilled in the art can flexibly select the ions according to actual requirements, for example, the ions may be boron ions or aluminum ions.

According to an embodiment of the present disclosure, the specific method of the N-type ion doping and the P-type ion doping are not limited, and those skilled in the art can adopt any feasible method, such as ion implantation. Therefore, the process is mature and easy to be implemented.

It should be understood by those skilled in the art that the manufacturing process of the CMOS thin film transistor includes, in addition to the N-type ion doping and the P-type ion doping mentioned above, processes for manufacturing other necessary structures in a conventional CMOS thin film transistor, such as processes for manufacturing structures such as a light blocking layer, a buffer layer, a via hole, a source electrode, a drain electrode, and the like.

In another aspect of the present disclosure, there is provided a CMOS thin film transistor. According to an embodiment of the present disclosure, the CMOS thin film transistor is manufactured by the method described above. Therefore, the CMOS thin film transistor has advantages of being manufactured by a short period, a low manufacturing cost, and still has good characteristics and service performances. As can be appreciated by those skilled in the art, the CMOS thin film transistor has all features and advantages of the method described above, and thus will not be described in detail here.

According to an embodiment of the present disclosure, the CMOS thin film transistor includes an N-type thin film transistor and a P-type thin film transistor, specifically: referring to FIG. 15, the N-type thin film transistor includes a first heavily doped drain region 110, lightly doped drain regions 120, a first gate inner region 130 and a first heavily doped source region 140, where an orthographic projection of the first gate inner region 130 on the substrate 10 is overlapped with an orthographic projection of the first gate electrode 71 on the substrate 10, the lightly doped drain regions 120 are disposed at two opposite ends of the first gate inner region 130, the first heavily doped drain region 110 is disposed at an end of a lightly doped drain region 120 away from the first gate inner region 130, and the first heavily doped source region 140 is disposed at another end of the lightly doped drain region 120 away from the first gate inner region 130; the P-type thin film transistor includes a second heavily doped drain region 210, a second gate inner region 220 and a second heavily doped source region 230, where an orthographic projection of the second gate inner region 220 on the substrate 10 is overlapped with an orthographic projection of the second gate electrode 72 on the substrate 10, and the second heavily doped drain region 210 and the second heavily doped source region 230 are respectively disposed at two opposite ends of the second gate inner region 220.

According to an embodiment of the present disclosure, the CMOS thin film transistor can be manufactured by the method described above, and it should be understood by those skilled in the art that the first heavily doped drain region 110 is located at the same position as the first region described above, the lightly doped drain regions 120 are located at the same positions as the second region and the fourth region described above, the first gate inner region 130 is located at the same position as the third region described above, the first heavily doped source region 140 is located at the same position as the fifth region described above, the second heavily doped drain region 210 is located at the same position as the sixth region described above, the second gate inner region 220 is located at the same position as the seventh region described above, and the second heavily doped source region 230 is located at the same position as the eighth region described above.

In yet another aspect of the present disclosure, there is provided an array substrate. According to an embodiment of the present disclosure, the array substrate includes the CMOS thin film transistor described above. Therefore, in addition to ensuring good characteristics and service performances of the array substrate, the array substrate is manufactured by a short period, the manufacturing cost of the array substrate is reduced, and the market competitiveness thereof is improved. As should be understood by those skilled in the art, the array substrate has all features and advantages of the CMOS thin film transistor described above, and thus will not be described in detail here.

It should be understood by those skilled in the art that, in addition to the CMOS thin film transistors described above, the array substrate described above may further include other necessary structures in a conventional array substrate, such as a connecting wire, a common electrode, a pixel electrode, and the like.

In still another aspect of the present disclosure, there is provided a display device. According to an embodiment of the present disclosure, the display device includes the array substrate as described above. Therefore, the display device is manufactured by a short period and a low manufacturing cost, has good characteristics and service performances, and can greatly improve the market competitiveness thereof. As should be understood by those skilled in the art, the display device has all features and advantages of the array substrate described above, and thus the description thereof is not repeated here.

According to an embodiment of the present disclosure, the specific type of the display device is not particularly limited, and those skilled in the art can flexibly select the display device according to actual situations, for example, the display device may be a display device such as a mobile phone, a tablet computer, a game machine, and a smart device with a display function.

It should be understood by those skilled in the art that the display device described above includes, in addition to the array substrate described above, structures or components necessary for a conventional display device, such as a mobile phone. Besides the array substrate, the display device further includes necessary structures or parts such as a color filter substrate, a touch screen, a voice module, a camera module, a CPU (central processing unit) processor and the like.

In the present disclosure, it should be understood that terms “central”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, or the like are used in orientations and positional relationships indicated in the drawings for convenience in describing the present disclosure and to simplify the description, but are not intended to indicate or imply that the device or element so referred to must have a particular orientation, be constructed and operated in a particular orientation, and are not to be construed as limiting the disclosure.

Furthermore, terms “first” and “second” are used for descriptive purposes only and are not to be construed as indicating or implying relative importance or to implicitly indicate the number of technical features indicated. Thus, a feature defined by the term “first” or “second” may explicitly or implicitly include one or more such features. In the description of the present disclosure, “a plurality” means two or more, unless specifically limited otherwise.

In the description of the present specification, terms “an embodiment”, “some embodiments”, “an example”, “a specific example”, “some examples” or the like means that a particular feature, structure, material, or characteristic described in connection with the embodiment or example is included in at least one embodiment or example of the present disclosure. In this specification, the schematic representations of the terms used above are not necessarily intended to refer to a same embodiment or example. Furthermore, particular features, structures, materials, or characteristics described may be combined in any suitable manner in any one or more embodiments or examples. Moreover, various embodiments or examples and features of various embodiments or examples described in this specification can be combined by those skilled in the art without contradiction.

While embodiments of the present disclosure have been shown and described above, it should be understood that the above embodiments are exemplary and not to be construed as limiting the present disclosure, and that changes, modifications, substitutions and alterations may be made to the above embodiments by those skilled in the art within the scope of the present disclosure.

1. A method for manufacturing a CMOS thin film transistor, comprising:
step 1, forming a semiconductor layer on a substrate, wherein the semiconductor layer comprises an N-type region and a P-type region which are arranged in a single layer and are spaced apart from each other,
the N-type region is divided into a first region, a second region, a third region, a fourth region and a fifth region which are arranged successively, and is used for forming an N-type thin film transistor, the first region is used for forming a first heavily doped drain region, the second region and the fourth region are used for forming lightly doped drain regions, the third region is used for forming a first gate inner region, and the fifth region is used for forming a first heavily doped source region,
the P-type region is divided into a sixth region, a seventh region and an eighth region which are arranged successively, and is used for forming a P-type thin film transistor, wherein the sixth region is used for forming a second heavily doped drain region, the seventh region is used for forming a second gate inner region, and the eighth region is used for forming a second heavily doped source region;
step 2, performing a first N-type ion doping on the first region and the fifth region;
step 3, performing a first P-type ion doping on the N-type region;
step 4, performing a second P-type ion doping on the N-type region and the P-type region after the step 3;
step 5, performing a second N-type ion doping on the first region, the second region, the fourth region, the fifth region, the sixth region and the eighth region after the step 4;
step 6, performing a third P-type ion doping on the sixth region and the eighth region after the step 5,
wherein the first N-type ion doping and the first P-type ion doping are performed by using a single halftone mask plate.

2. The method of claim 1, wherein the first N-type ion doping and the first P-type ion doping comprise:
forming a first patterned photoresist layer on an upper surface of the semiconductor layer by using the halftone mask plate, the first patterned photoresist layer comprises a first layer and a second layer, the first layer covers a surface of the P-type region, and the second layer covers surfaces of the second region, the third region and the fourth region, a thickness of the second layer is smaller than a thickness of the first layer;
performing the first N-type ion doping on the first region and the fifth region which are exposed;
removing the second layer, and thinning the first layer so as to obtain a second patterned photoresist layer, the second patterned photoresist layer covers the surface of the P-type region;
performing the first P-type ion doping on the N-type region which is exposed; and
removing the second patterned photoresist layer.

3. The method of claim 2, wherein by an ashing process, the second layer is removed and the first layer is thinned to obtain the second patterned photoresist layer.

4. The method of claim 2, wherein the thickness of the second layer ranges from 30% of the thickness of the first layer to 70% of the thickness of the first layer.

5. The method of claim 4, wherein the thickness of the first layer ranges from 1 μm to 2.5 μm, the thickness of the second layer ranges from 0.5 μm to 1.75 μm, and a time duration of the ashing process ranges from 10 seconds to 40 seconds.

6. The method of claim 2, wherein a thickness of the second patterned photoresist layer ranges from 30% of the thickness of the first layer to 70% of the thickness of the first layer.

7. The method of claim 1, further comprising:
after the second P-type ion doping and before the second N-type ion doping, forming a gate insulating layer on surfaces of the N-type region and the P-type region;
forming a first gate electrode and a second gate electrode on a surface of the gate insulating layer, wherein an orthogonal projection of the first gate electrode on the substrate is overlapped with an orthogonal projection of the third region on the substrate, and an orthogonal projection of the second gate electrode on the substrate is overlapped with an orthogonal projection of the seventh region on the substrate, and
the second N-type ion doping is performed by taking the first gate electrode and the second gate electrode as masks.

8. The method of claim 7, wherein the third P-type ion doping comprises:
forming a third patterned photoresist layer on the surface of the N-type region corresponding to the gate insulating layer, the third patterned photoresist layer covers the first gate electrode, and the third patterned photoresist layer and the second gate electrode are used as masks for performing the third P-type ion doping on the sixth region and the eighth region.

9. The method of claim 1, wherein the semiconductor layer is a polycrystalline layer.

10. A CMOS thin film transistor, manufactured by the method of claim 1.

11. The CMOS thin film transistor of claim 10, comprising an N-type thin film transistor and a P-type thin film transistor, wherein,
the N-type thin film transistor comprises a first heavily doped drain region, lightly doped drain regions, a first gate inner region and a first heavily doped source region, an orthographic projection of the first gate inner region on a substrate is overlapped with an orthographic projection of a first gate electrode on the substrate, the lightly doped drain regions are arranged at two opposite ends of the first gate inner region, the first heavily doped drain region is arranged at an end, away from the first gate inner region, of a lightly doped drain region, and the first heavily doped source region is arranged at another end, away from the first gate inner region, of the lightly doped drain region;
the P-type thin film transistor comprises a second heavily doped drain region, a second gate inner region and a second heavily doped source region, an orthographic projection of the second gate inner region on the substrate is overlapped with an orthographic projection of the second gate electrode on the substrate, and the second heavily doped drain region and the second heavily doped source region are respectively arranged at two opposite ends of the second gate inner region.

12. An array substrate, comprising the CMOS thin film transistor of claim 10.

13. An array substrate, comprising the CMOS thin film transistor of claim 11.
